(19) United States
(12) Patent Application Publication
(10) Pub. No.: US 2026/0169396 A1
(43) Pub. Date: Jun. 18, 2026

(54) INSPECTION APPARATUS

(71) Applicant: SAMSUNG ELECTRONICS CO., LTD., Suwon-si (KR)

(72) Inventors: Hyeon Jin KIM, Suwon-si (KR); JONGGU LEE, Suwon-si (KR); Won yeon JEONG, Suwon-si (KR); DONG-WOOK KIM, Suwon-si (KR); Seunguk PARK, Suwon-si (KR); DONGSIK JEONG, Suwon-si (KR); YONGSUK CHOI, Suwon-si (KR)

(73) Assignee: SAMSUNG ELECTRONICS CO., LTD., Suwon-si (KR)

(21) Appl. No.: 19/345,729

(22) Filed: Sep. 30, 2025

(30) Foreign Application Priority Data
Dec. 17, 2024 (KR) 10-2024-0188030

(51) Int. Cl. G03F 7/00; H01L 21/687

(52) U.S. Cl. CPC G03F 7/70783; G03F 7/7085; H10P 72/7624

(57) ABSTRACT

Provided is an inspection apparatus including a supporter extending in a first direction, an inspection body connected to a first end portion of the supporter to support the supporter, and a first optical system and a second optical system connected to a second end portion of the supporter opposite to the first end portion of the supporter, wherein the first optical system is configured to obtain a two-dimensional image of a first surface of a chuck, and the second optical system is configured to obtain three-dimensional profile data of the first surface of the chuck.

### CROSS-REFERENCE TO RELATED APPLICATIONS

This patent application claims priority to Korean Patent Application No. 10-2024-0188030, filed on Dec. 17, 2024, the disclosure of which is incorporated herein in its entirety by reference.

### BACKGROUND

Embodiments of the present disclosure described herein relate to an inspection apparatus, and more particularly, relate to an inspection apparatus capable of inspecting a surface of an inspection target.

Semiconductor devices may be manufactured through various manufacturing processes. For example, semiconductor devices may be manufactured using photolithography processes, etching processes, ion implantation processes, polishing processes, and deposition processes. In semiconductor manufacturing apparatuses where these processes are performed, a device may be provided to hold a substrate. The device that holds the substrate may be a chuck. However, the surface of the substrate held in the chuck may not be flat when the chuck is defective. In this case, the reliability of semiconductor manufacturing processes may be deteriorated. Accordingly, various inspection methods for inspecting defects in the chuck are being researched.

### SUMMARY

One or more embodiments provide an inspection apparatus capable of inspecting a surface of an inspection target.

One or more embodiments also provide an inspection apparatus capable of inspecting an upper surface of a chuck.

One or more embodiments provide an inspection apparatus capable of obtaining a two-dimensional image and three-dimensional profile data of the upper surface of the chuck and analyzing the two-dimensional image and the three-dimensional profile data.

According to an aspect of one or more embodiments, there is provided an inspection apparatus including a supporter extending in a first direction, an inspection body connected to a first end portion of the supporter to support the supporter, and a first optical system and a second optical system connected to a second end portion of the supporter opposite to the first end portion of the supporter, wherein the first optical system is configured to obtain a two-dimensional image of a first surface of a chuck, and the second optical system is configured to obtain three-dimensional profile data of the first surface of the chuck.

According to another aspect of one or more embodiments, there is provided an inspection apparatus including a first optical system configured to obtain a two-dimensional image of a first surface of a chuck that includes a chuck body and support pillars on the chuck body, a second optical system configured to obtain three-dimensional profile data of the support pillars, a supporter extending in a first direction, and an inspection body including at least one processor configured to analyze the two-dimensional image and the three-dimensional profile data, wherein the inspection body is connected to a first end portion of the supporter, and the first optical system and the second optical system are connected to a second end portion of the supporter opposite to the first end portion of the supporter.

According to still another aspect of one or more embodiments, there is provided an inspection apparatus including a first optical system configured to obtain a two-dimensional image of a first surface of an inspection target, a second optical system configured to obtain three-dimensional profile data of the first surface of the inspection target, a supporter extending in a first direction, and an inspection body including at least one processor configured to analyze the two-dimensional image and the three-dimensional profile data to obtain at least one of a size of the three-dimensional profile data of the first surface, a height of the three-dimensional profile data of the first surface, and a depth of the three-dimensional profile data of the first surface, wherein the inspection body is connected to a first end portion of the supporter, and the first optical system and the second optical system are connected to a second end portion of the supporter opposite to the first end portion of the supporter.

### BRIEF DESCRIPTION OF DRAWINGS

Embodiments will be more clearly understood from the following detailed description taken in conjunction with the accompanying drawings in which:

FIG. 1 is a perspective view illustrating an inspection apparatus according to one or more embodiments;

FIG. 2 is a perspective view illustrating an inspection apparatus according to one or more embodiments;

FIG. 3 is an enlarged lateral view illustrating an area S1 of FIG. 2;

FIG. 4 is a schematic diagram illustrating a first optical system according to one or more embodiments;

FIG. 5 is a schematic diagram illustrating a second optical system according to one or more embodiments;

FIG. 6 is a perspective view illustrating an inspection apparatus and semiconductor manufacturing apparatus according to one or more embodiments;

FIG. 7 is a perspective view illustrating a chuck according to one or more embodiments;

FIG. 8 is an enlarged plan view illustrating an area S2 of FIG. 7;

FIG. 9 is a cross-sectional view taken along a line A-A′ of FIG. 8;

FIG. 10 is a cross-sectional view taken along a line B-B′ of FIG. 8;

FIG. 11 is a cross-sectional view taken along a line C-C′ of FIG. 8 and illustrating a chuck holding a substrate according to one or more embodiments;

FIG. 12 is an enlarged plan view corresponding to the area S2 of FIG. 7 and illustrating a chuck according to one or more embodiments;

FIG. 13 is a view illustrating analysis results of the inspection apparatus according to one or more embodiments;

FIG. 14 is a cross-sectional view taken along a line I-I′ of FIG. 12;

FIG. 15 is a cross-sectional view taken along a line II-II′ of FIG. 12; and

FIG. 16 is an enlarged lateral view corresponding to the area S1 of FIG. 2 and illustrating an inspection apparatus according to one or more embodiments.

### DETAILED DESCRIPTION

Hereinafter, embodiments of the present disclosure will be described with reference to accompanying drawings. Embodiments described herein are example embodiments, and thus, the disclosure is not limited thereto.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

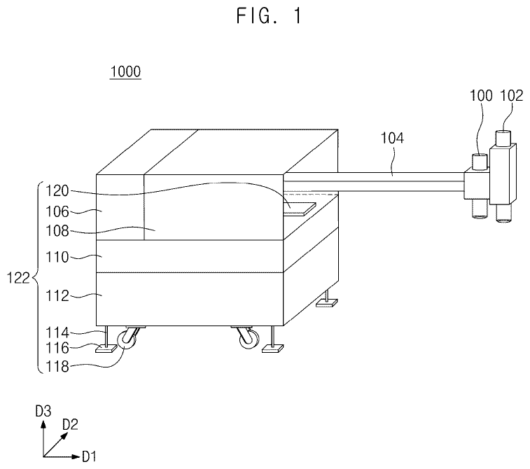

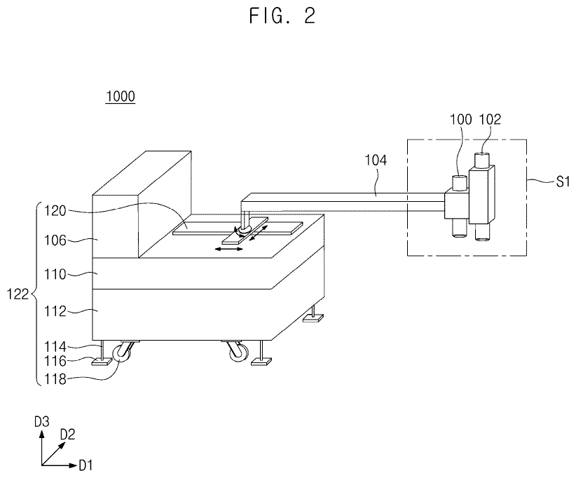

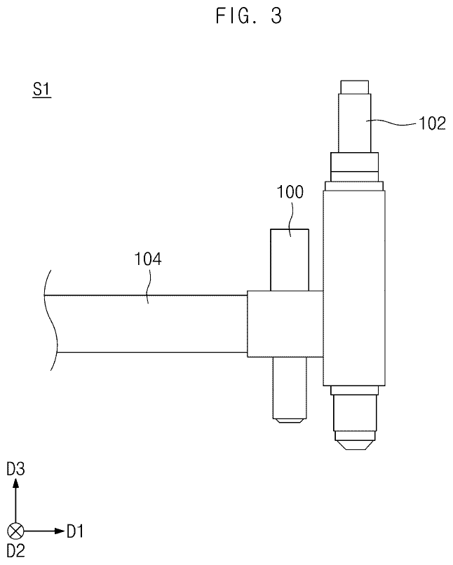

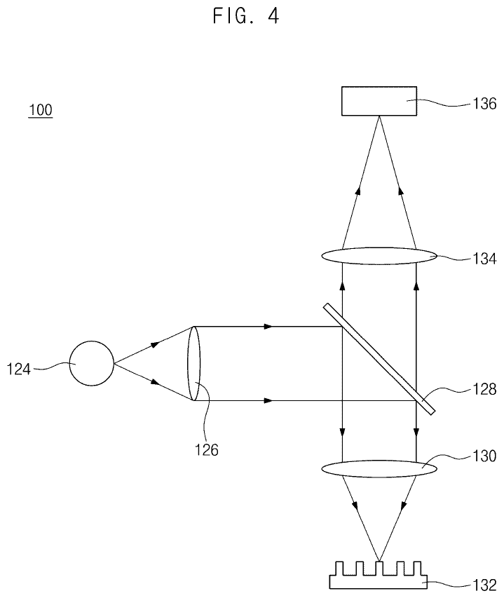

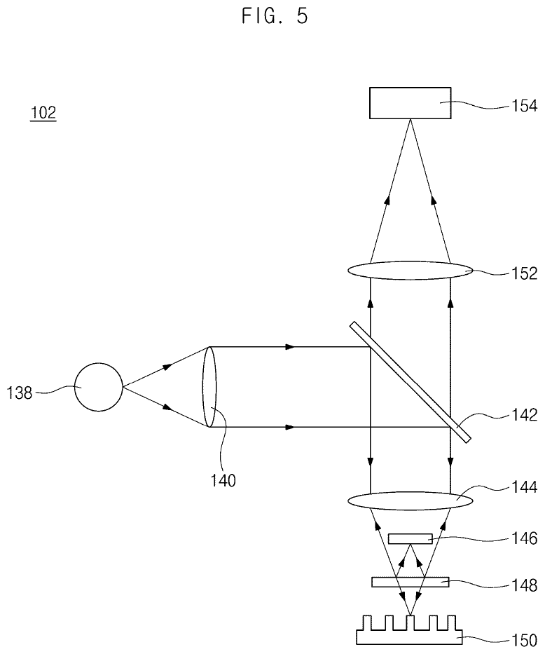

FIG. 1 is a perspective view illustrating an inspection apparatus 1000 according to one or more embodiments. FIG. 2 is a perspective view illustrating an inspection apparatus 1000 according to one or more embodiments. In FIG. 2, a shielding structure 108 is omitted to show the inside of an inspection body 122. FIG. 3 is an enlarged lateral view illustrating an area S1 of FIG. 2. FIG. 4 is a schematic diagram illustrating a first optical system according to one or more embodiments. FIG. 5 is a schematic diagram illustrating a second optical system according to one or more embodiments.

Referring to FIGS. 1 to 5, the inspection apparatus 1000 may include a first optical system 100, a second optical system 102, a supporter 104, and the inspection body 122. The inspection body 122 may include a controller 106, the shielding structure 108, a surface plate 110, a multi-axis rotary stage 120, a height adjuster 114, a fixed support 116, and a moving unit 118. The inspection body 122 may further include a vibration damper 112.

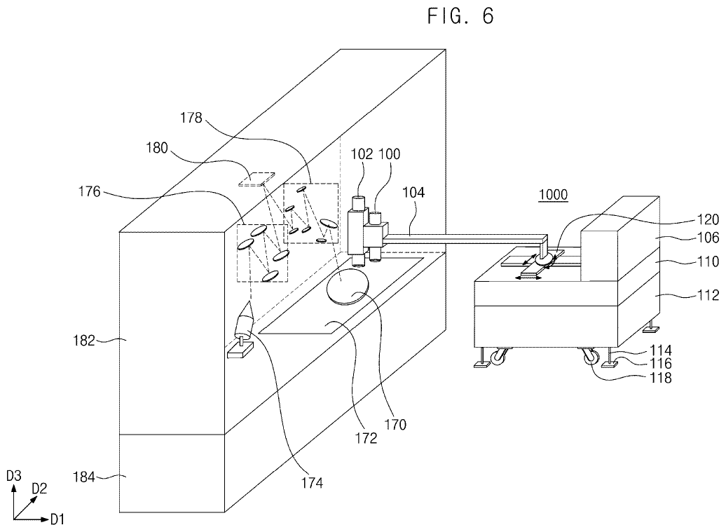

The first optical system 100 may be configured to obtain a two-dimensional image of one surface of an inspection target. The one surface of the inspection target may be an upper surface of a chuck 170 (refer to FIG. 6) provided in semiconductor manufacturing apparatus. For example, the first optical system 100 may obtain the two-dimensional image of the upper surface of the chuck 170. The first optical system 100 may measure or inspect the upper surface of the chuck 170. Accordingly, a defective portion occurring in the upper surface of the chuck 170 may be measured by the first optical system 100. A magnification of the first optical system 100 may be adjusted as needed. The magnification of the first optical system 100 may be determined in consideration of a time required for the first optical system 100 to measure the upper surface of the chuck 170. The first optical system 100 may have a resolution from about 500 nm to about 1 μm, however, embodiments are not limited thereto.

The first optical system 100 may be an optical microscope or an optical camera. According to another example, the first optical system 100 may be another optical system capable of measuring the upper surface of the chuck 170. Hereinafter, for the convenience of explanation, the optical microscope will be described as a representative example of the first optical system 100. As an example, the first optical system 100 may include a first light source 124 as shown in FIG. 4. The first light source 124 may emit light. Since the first optical system 100 includes the first light source 124, the first optical system 100 may measure the upper surface of the chuck 170 without being affected by light quantity in an inspection environment and conditions of the semiconductor manufacturing apparatus. The first optical system 100 may further include a first collimation lens 126, a first optical splitter 128, a first objective lens 130, a first imaging lens 134, and a first detector 136. The light emitted from the first light source 124 may pass through the first collimation lens 126. The first collimation lens 126 may be configured to convert the light that diverges or converges into collimated light. The collimated light may have a more precise direction and focus compared to the non-collimated light and may be transmitted more efficiently. Accordingly, the accuracy of the two-dimensional image obtained by the first optical system 100 may be improved. The collimated light may be reflected by the first optical splitter 128 and may pass through the first objective lens 130. The collimated light may be reflected by a first measuring object 132 after passing through the first objective lens 130. The reflected light may be imaged by the first imaging lens 134. An image may be formed by the imaging process, and the image may be detected by the first detector 136.

The second optical system 102 may be configured to obtain three-dimensional profile data of a surface of the inspection target, e.g., the upper surface of the chuck 170. The second optical system 102 may measure or inspect the entire upper surface of the chuck 170. According to one or more embodiments, the second optical system 102 may measure or inspect only a portion of the upper surface of the chuck 170. The second optical system 102 may have a resolution within a range from about 1 nm to about 900 nm, however, embodiments are not limited thereto.

The second optical system 102 may obtain the three-dimensional profile data of the upper surface of the chuck 170 using an interference phenomenon of light, however, embodiments are not limited thereto. The second optical system 102 may be another optical system capable of obtaining the three-dimensional profile data of the upper surface of the chuck 170. Hereinafter, for the convenience of explanation, the second optical system 102 using the interference phenomenon of light will be described as a representative example.

The second optical system 102 may measure or inspect an interference pattern of light. As an example, the second optical system 102 may include an optical interference system. The optical interference system may split light into a measurement light and a reference light. The measurement light reflected and returned from a measurement surface and the reference light reflected and returned from a reference surface may be recombined. In this example, a phase difference may occur due to a difference in travel distance between the two lights. The interference pattern may be generated by the phase difference. The second optical system 102 may measure or inspect the interference pattern.

In one or more embodiments, the second optical system 102 may include at least one of various interferometers. The various interferometers may include a Mirau interferometer, a Michelson-Morley interferometer, and a Mach-Zehnder interferometer. Hereinafter, for the convenience of explanation, the second optical system 102 using the Mirau interferometer will be described as a representative example.

Referring to FIG. 5, the second optical system 102 may include a second light source 138. The second light source 138 may emit light. The second light source 138 may emit, for example, white light. For example, the second optical system 102 may be a white light interference system. However, embodiments are not limited thereto. The second optical system 102 may further include a second collimation lens 140, a second optical splitter 142, a second objective lens 144, a third optical splitter 148, a second imaging lens 152, a reference mirror 146, and a second detector 154. The light emitted from the second light source 138 may pass through the second collimation lens 140. The second collimation lens 140 may be configured to convert the light that diverges or converges into a collimated light. The collimated light may have a more precise direction and focus compared to the light emitted from the second light source 138 and may be transmitted more efficiently. Accordingly, the accuracy of the three-dimensional image data obtained by the second optical system 102 may be improved. The collimated light may be reflected by the second optical splitter 142 and may pass through the second objective lens 144. A portion of the collimated light may pass through the third optical splitter 148 after passing through the second objective lens 144, and the other portion of the collimated light may be reflected by the third optical splitter 148. The light that passes through the third optical splitter 148 may be referred to as a measurement light. The light that is reflected by the third optical splitter 148 may be referred to as a reference light. According to one or more embodiments, the second collimation lens 140 may be omitted.

The measurement light may pass through the third optical splitter 148. The measurement light that passes through the third optical splitter 148 may be reflected by a surface of a second measuring object 150. The reflected measurement light may sequentially pass through the third optical splitter 148, the second objective lens 144, and the second optical splitter 142 and may reach the second imaging lens 152.

The reference light may be reflected by the third optical splitter 148. The reference light reflected by the third optical splitter 148 may be incident on the reference mirror 146 disposed between the second objective lens 144 and the third optical splitter 148. The reference light incident on the reference mirror 146 may be reflected by the reference mirror 146. The reference light reflected by the reference mirror 146 may be reflected by the third optical splitter 148. The reference light reflected by the third optical splitter 148 may sequentially pass through the second objective lens 144 and the second optical splitter 142 and may reach the second imaging lens 152.

The reference light and the measurement light, which travel along different paths, may be combined with each other. Accordingly, the interference pattern having bright regions and dark regions may be generated. The second detector 154 may detect the interference pattern. The controller 106 provided in the inspection apparatus 1000 may analyze the detected interference pattern and may obtain the three-dimensional profile data from the analyzed results.

The supporter 104 may extend in a first direction D1. The supporter 104 may be a cantilever. For example, a first end portion of the supporter 104 may be fixed to the multi-axis rotary stage 120, and a second end portion of the supporter 104 opposite to the first end portion of the supporter 104 in the first direction D1 may not be fixed. Accordingly, the second end portion may be free to move. The first end portion of the supporter 104 may be coupled with the inspection body 122. For example, the first end portion of the supporter 104 may be fixed to the multi-axis rotary stage 120 as described above. A portion of the supporter 104 and the second end portion of the supporter 104 may protrude from the inspection body 122. The first and second optical systems 100 and 102 may be coupled and/or connected to the second end portion of the supporter 104. The first and second optical systems 100 and 102 may be arranged in the first direction D1. According to one or more embodiments, the first and second optical systems 100 and 102 may be arranged in a second direction D2 intersecting the first direction D1, however, embodiments are not limited thereto.

An upper surface of the surface plate 110 may be flat, and thus, the upper surface of the surface plate 110 may be used as a plane on which precise processes are performed. The surface plate 110 may include, for example, cast iron or stone, and the weight of the cast iron or stone may reduce vibration. As another example, the surface plate 110 may include, for example, aluminum or stainless steel and may have a honeycomb structure. The vibration may be reduced by the honeycomb structure, however, embodiment are not limited thereto. The surface plate 110 may reduce vibration generated from a floor where the inspection body 122 is placed. In addition, the surface plate 110 may reduce vibration generated in processes performed on the surface plate 110. The multi-axis rotary stage 120 may be provided on the upper surface of the surface plate 110. The surface plate 110 may maintain a horizontal state of the multi-axis rotary stage 120. In addition, the surface plate 110 may reduce vibration generated from the multi-axis rotary stage 120.

The multi-axis rotary stage 120 may be coupled and/or connected with the first end portion of the supporter 104. For example, the first end portion of the supporter 104 may be fixed to the multi-axis rotary stage 120 as described above. The multi-axis rotary stage 120 may move the supporter 104 two-dimensionally. The multi-axis rotary stage 120 may rotate the supporter 104. The multi-axis rotary stage 120 may include two linear motion guides and one rotational motion guide. One of the two linear motion guides may extend in the first direction D1. The other of the two linear motion guides may extend in the second direction D2. The two linear motion guides may be coupled to each other. The two linear motion guides may guide the movement of the supporter 104 in the first direction D1 and the second direction D2. The rotational motion guide may be coupled to one of the two linear motion guides. The rotational motion guide may guide the rotational motion of the supporter 104. The linear motion guides may include bearings. The bearings may reduce friction generated during the linear motion of the linear motion guides. The rotational motion guide may include bearings. The bearings may reduce friction generated during the rotational motion of the rotational motion guide. Accordingly, the supporter 104 may move more precisely. The supporter 104 may move by the multi-axis rotary stage 120, and thus, the first and second optical systems 100 and 102 coupled and/or connected with the second end portion of the supporter 104 may be moved. For example, the first and second optical systems 100 and 102 may move to measure the upper surface of the chuck 170 by the multi-axis rotary stage 120.

The shielding structure 108 may be provided on and/or cover the multi-axis rotary stage 120 and the first end portion of the supporter 104 and may have an open side. The portion of the supporter 104 and the second end portion of the supporter 104 may protrude laterally through the open side of the shielding structure 108 in the first direction D1. The shielding structure 108 may be attached to and detached from the inspection body 122.

The controller 106 may control the movement of the first and second optical systems 100 and 102. In addition, the controller 106 may store the two-dimensional image and the three-dimensional profile data respectively provided from the first and second optical systems 100 and 102. In addition, the controller 106 may analyze the two-dimensional image and the three-dimensional profile data. The controller 106 may include a storage device, a processor, and a display device to perform these operations.

The processor of the controller 106 may control the operation of the multi-axis rotary stage 120. The operation of the supporter 104 coupled to the multi-axis rotary stage 120 may be controlled by the control of the processor, and thus, the movement of the first and second optical systems 100 and 102 may be controlled. For example, the processor may control the multi-axis rotary stage 120 to allow the first and second optical systems 100 and 102 to move over the chuck 170.

The processor may control the operation of the first optical system 100. The first optical system 100 may obtain the two-dimensional image of the upper surface of the chuck 170 by the control of the processor. The processor may analyze the two-dimensional image obtained from the first optical system 100. In more detail, the processor may analyze the two-dimensional image and may analyze the defective portion in the upper surface of the chuck 170. As an example, the processor may analyze the two-dimensional image to calculate (obtain) a position of the defective portion and/or a size of the defective portion. In addition, the processor may classify the type of the defective portion. The type of the defective portion may be defined in advance.

The processor may control the operation of the second optical system 102. The second optical system 102 may obtain the three-dimensional profile data of the upper surface of the chuck 170 by the control of the processor. According to one or more embodiments, the second optical system 102 may obtain the three-dimensional profile data of the portion of the upper surface of the chuck 170 by the control of the processor. The portion of the upper surface of the chuck 170 may be determined from the two-dimensional image obtained by the first optical system 100. For example, the processor may calculate (obtain) the position of the portion whose three-dimensional profile data are required from the two-dimensional image. The processor may analyze the three-dimensional profile data. In more detail, the processor may analyze the three-dimensional profile data to analyze the defective portion in the upper surface of the chuck 170. The processor may calculate (obtain) at least one of the size of the defective portion, a height of the defective portion, and a depth of the defective portion.

The processor may store the two-dimensional image and the three-dimensional profile data in the storage device and may display the analyzed data through the display device. In addition, programs to perform these operations may be stored in the storage device.

The vibration damper 112 may reduce the vibration generated from the floor where the inspection body 122 is located. In addition, the vibration damper 112 may reduce the vibration generated from devices, such as the multi-axis rotary stage 120, the controller 106, etc., included in the inspection body 122. The vibration damper 112 may operate in an active vibration control method. The active vibration control method may sense the vibration using a sensor attached to the vibration damper 112 and compensate for the vibration using a motor, however, embodiments are not limited thereto. The vibration damper 112 may be disposed under the surface plate 110, however, embodiments are not limited thereto.

The inspection body 122 may be portable by the moving unit 118. The moving unit 118 may move the inspection body 122, the supporter 104, and the first and second optical systems 100 and 102. The moving unit 118 may be coupled with a lower surface of the surface plate 110. According to an embodiment, in a case where the inspection body 122 includes the vibration damper 112, the moving unit 118 may be coupled with and/or connected to a lower surface of the vibration damper 112, however, the coupling position of the moving unit 118 is not limited thereto. The moving unit 118 may be in contact with a ground or may be separated from the ground. As shown in FIGS. 1 and 2, the moving unit 118 may be wheels, however, embodiments are not limited thereto.

An upper portion of the height adjuster 114 may be coupled with and/or connected to the lower surface of the surface plate 110. According to one or more embodiments, in a case where the inspection body 122 includes the vibration damper 112, the upper portion of the height adjuster 114 may be coupled with and/or connected to the lower surface of the vibration damper 112. However, the coupling position of the height adjuster 114 is not limited thereto. The fixed support 116 may be coupled with and/or connected to a lower portion of the height adjuster 114. The fixed support 116 may be in contact with the ground by the height adjuster 114. Accordingly, the fixed support 116 may fix the inspection body 122. The movement of the inspection body 122 may be restricted by the fixed support 116 that is in contact with the ground, and thus, the inspection body 122 may have increased resistance to vibration. According to one or more embodiments, the fixed support 116 may be separated from the ground by the height adjuster 114.

The inspection body 122 may be fixed in place or moved by adjusting the moving unit 118, the height adjuster 114, and the fixed support 116. When moving the inspection body 122, the fixed support 116 may be spaced apart from the ground and the moving unit 118 may be brought into contact with the ground using the height adjuster 114 to move the inspection body 122. When fixing the inspection body 122 in place, the moving unit 118 may be spaced apart from the ground and the fixed support 116 may be brought into contact with the ground using the height adjuster 114 to fix the inspection body 122 in place.

The inspection body 122 may further include a position recognition system to align the first and second optical systems 100 and 102. The position recognition system may be an optical system or may be another device capable of recognizing positions of the first and second optical systems 100 and 102. The position recognition system may obtain position coordinates of the first and second optical systems 100 and 102. The controller 106 may determine the positions of the first and second optical systems 100 and 102 in a third direction D3 using the position recognition system. Accordingly, the controller 106 may control the first and second optical systems 100 and 102 not to collide with the chuck 170 that is the inspection target, however, embodiments are not limited thereto. As an example, the controller 106 may determine the positions of the first and second optical systems 100 and 102 in the third direction D3 using the first optical system 100.

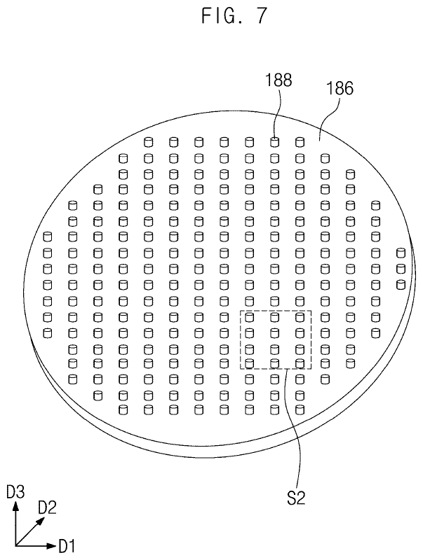

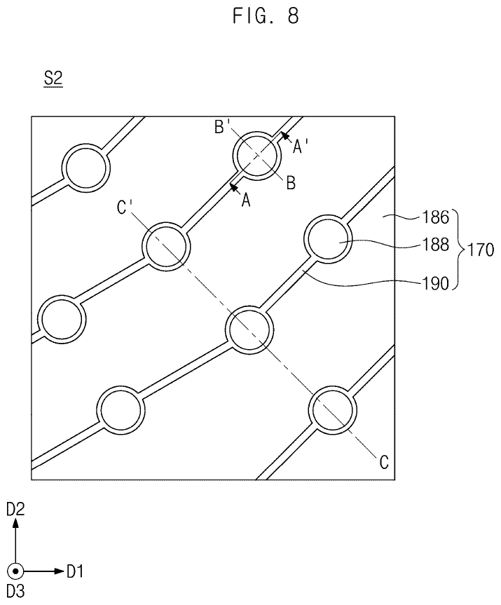

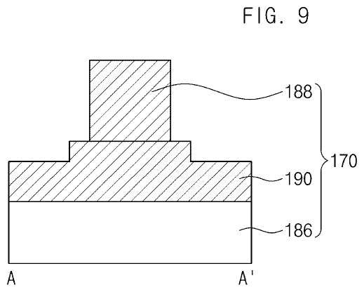

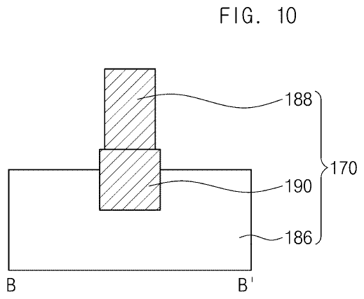

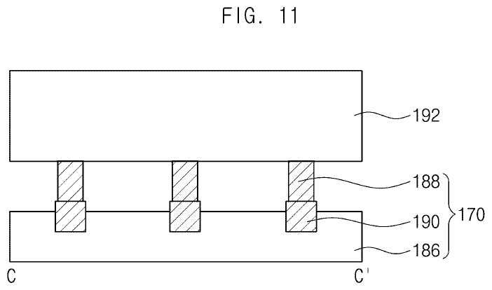

FIG. 6 is a perspective view illustrating the inspection apparatus and the semiconductor manufacturing apparatus according to one or more embodiments. FIG. 7 is a perspective view illustrating the chuck 170 according to one or more embodiments. FIG. 8 is an enlarged plan view illustrating an area S2 of FIG. 7. FIG. 9 is a cross-sectional view taken along a line A-A′ of FIG. 8. FIG. 10 is a cross-sectional view taken along a line B-B′ of FIG. 8. FIG. 11 is a cross-sectional view taken along a line C-C′ of FIG. 8 and illustrating the chuck 170 holding a substrate 192 according to one or more embodiments.

Referring to FIGS. 6 to 11, the inspection apparatus 1000 may inspect the chuck 170 provided in the semiconductor manufacturing apparatus. When inspecting the chuck 170, the first and second optical systems 100 and 102 may be located inside the semiconductor manufacturing apparatus, and the inspection body 122 may be located outside the semiconductor manufacturing apparatus. In addition, the first and second optical systems 100 and 102 may be spaced apart from units in the semiconductor manufacturing apparatus during the inspection. For example, when the inspection apparatus 1000 measures and inspects the chuck 170, the inspection apparatus 1000 may not be in contact with the semiconductor manufacturing apparatus.

In one or more embodiments, the semiconductor manufacturing apparatus may be one of various semiconductor manufacturing apparatuses including chucks. According to one or more embodiments, the semiconductor manufacturing apparatus may be an exposure apparatus as shown in FIG. 6.

The chuck 170 may be placed in the semiconductor manufacturing apparatus. According to one or more embodiments, the chuck 170 may be placed in the exposure apparatus. The chuck 170 placed in the exposure apparatus may hold the substrate 192. In addition, the chuck 170 may move at a relatively high speed while holding the substrate 192 during an exposure process.

The exposure apparatus may include an exposure chamber 182 and an exposure apparatus supporter 184. In addition, the exposure apparatus may further include the chuck 170, a chuck base 172, a light source 174, an illumination-optical system 176, a projection optical system 178, and a reticle stage 180 in the exposure chamber 182. The exposure chamber 182 may provide a space in which the exposure process is performed. The exposure chamber 182 may isolate the inside of the exposure chamber 182 from an external environment. The inside of the exposure chamber 182 may be set to a vacuum environment.

According to one or more embodiments, the exposure apparatus may be an exposure apparatus that uses extreme ultraviolet light. The light source 174 may irradiate (emit) the extreme ultraviolet light. As an example, the light source 174 may include a laser irradiation device that irradiates (emits) a laser beam with a relatively high-intensity pulse, a target material (e.g., tin), a chamber, and a condensing mirror. The laser irradiation device may irradiate (emit) a CO₂ laser beam onto the target material, and plasma may be generated from the target material in the chamber. In this process, the extreme ultraviolet light may be emitted from the plasma. The emitted extreme ultraviolet light may be condensed by the condensing mirror. The condensed extreme ultraviolet light may be irradiated (emitted) to the illumination-optical system 176. The extreme ultraviolet light may be shaped by the illumination-optical system 176. The illumination-optical system 176 may include mirrors, for example, multilayer thin film mirrors. Further, the illumination-optical system 176 may include various lenses and optical elements. The shaped extreme ultraviolet light may illuminate a reticle accommodated in the reticle stage 180. The reticle may have a specific pattern. The reticle may be a reflective reticle. The extreme ultraviolet light reflected by the reticle may be irradiated (emitted) onto the substrate provided on the chuck 170 through the projection optical system 178. In this manner, the specific pattern of the reticle may be transferred to a photosensitive film of the substrate. The projection optical system 178 may include mirrors, for example, multilayer thin film mirrors. Further, the projection optical system 178 may include various lenses and optical elements. During the exposure process, the chuck 170 holding the substrate 192 may move at a relatively high speed, and thus the entire upper surface of the substrate 192 may be exposed to light due to this movement of the chuck 170. Then, bake and development processes may be performed.

For example, the exposure apparatus may transfer the specific pattern of the reticle onto the upper surface of the substrate 192. The exposure apparatus may use the extreme ultraviolet light in the transfer process. The extreme ultraviolet light may have a property of being absorbed in the air. Accordingly, the inside of the exposure chamber 182 may be set to the vacuum environment during the exposure process to prevent the extreme ultraviolet light from being absorbed. The chuck 170 may hold the substrate 192 during the vacuum environment. The chuck 170 may be, but not limited to, an electrostatic chuck (ESC). The electrostatic chuck (ESC) may hold and support the substrate 192 by electrostatic force.

During the exposure process, the chuck 170 holding the substrate 192 may move at a relatively high speed. Due to this movement, a frictional force may be generated between the substrate 192 and the chuck 170. The chuck 170 may include protrusion portions that protrude upward, for example, burls, to reduce the frictional force. As an example, the chuck 170 may include a chuck body 186 and the protrusion portions that protrude upward from an upper surface of the chuck body 186. The substrate 192 may be loaded onto upper surfaces of the protrusion portions and may be supported by the protrusion portions. The total area of the upper surfaces of the protrusion portions may be within a range from about 0.1% to about 5% of the chuck 170 when viewed from a top plan view. A contact area between the substrate 192 and the chuck 170 may be reduced by the protrusion portions. Therefore, the frictional force between the substrate 192 and the chuck 170 may be reduced.

Each of the protrusion portions may have, for example, a cylindrical shape or a rectangular prism shape. For example, the chuck 170 may include the chuck body 186, support pillars 188, and a ground line 190 as shown in FIGS. 8 to 10. The ground line 190 may be disposed in a groove recessed from the upper surface of the chuck body 186, and the support pillars 188 may be disposed on the ground line 190. According to one or more embodiments, a plurality of grooves may be formed in the chuck body 186, and a plurality of ground lines 190 may be disposed in the grooves, respectively. The support pillars 188 may correspond to the protrusion portions. For example, each of the support pillars 188 may have a cylindrical shape or a rectangular prism shape. The support pillars 188 may be arranged laterally spaced apart from each other, and as shown in FIG. 11, the support pillars 188 may include upper surfaces that may hold the substrate 192. In some embodiments, thousands or tens of thousands of support pillars 188 may be disposed on the chuck body 186. The upper surface of the chuck 170 may include the upper surface of the chuck body 186 and the upper surfaces of the support pillars 188. The upper surface of each support pillar 188 may have a width ranging from tens to hundreds of micrometers (μm). The support pillars 188 may include a dielectric material, e.g., a glass material, or a conductive material. According to one or more embodiments, the support pillar 188 may include an inner portion including the dielectric material and a coating layer including the conductive material, e.g., chromium nitride (CrN) or titanium nitride (TiN), and disposed on a surface of the inner portion, however, embodiments are not limited thereto.

A ground voltage may be applied to the support pillars 188 through the ground line 190. When the substrate 192 is unloaded from the chuck 170, charges remaining on surfaces of the support pillars 188 may be removed by the ground voltage applied through the ground line 190. Accordingly, the substrate 192 may be more easily unloaded from the chuck 170. In one or more embodiments, the upper surface of the ground line 190 may be substantially coplanar with the upper surface of the chuck body 186 or may be higher than the upper surface of the chuck body 186 in the third direction D3, however, embodiments are not limited thereto.

As a semiconductor manufacturing process, for example, the exposure process, is performed repeatedly, the defective portion may occur on at least one of the support pillars 188. When the substrate 192 is held or loaded on the upper surfaces of the support pillars 188 or separated or unloaded from the upper surfaces of the support pillars 188, the defective portion may be generated in at least one of the support pillars 188. In addition, the defective portion may be generated by a foreign substance. Further, the defective portion may be generated due to the friction between the upper surfaces of the support pillars 188 and the substrate 192, however, embodiments are not limited thereto. The defective portion on at least one of the support pillars 188 may be caused by various other causes.

The substrate 192 may be held or loaded on the upper surfaces of the support pillars 188. Levels of the upper surfaces of the support pillars 188 may affect a level of a surface of the substrate 192 held on the upper surfaces of the support pillars 188 in the third direction D3. In a case where the defective portion occurs on at least one of the support pillars 188, a portion of the upper surface of the substrate 192, which corresponds to the defective portion, may be located at a different level from the level of the other portion of the upper surface of the substrate 192 in the third direction D3. As a result, the upper surface of the substrate 192 may not be flat. In addition, a roughness of the upper surface of the support pillar 188 on which the defective portion occurs may be different from a roughness of the upper surface of the support pillar 188 on which the defective portion does not occur. Accordingly, excessive frictional force may be concentrated on the support pillar 188 on which the defective portion occurs, causing deformation of the substrate 192 held on the support pillar 188. Consequently, reliability of the semiconductor manufacturing process may be deteriorated.

The chuck 170 may further include a gas supply device to control a temperature of the substrate 192. The gas supply device may supply gases, such as hydrogen or helium, into spaces between the support pillars 188, and the temperature of the substrate 192 may be controlled by the gases.

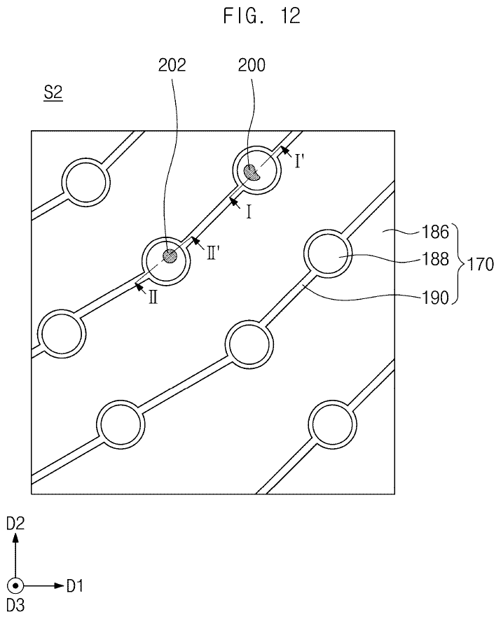

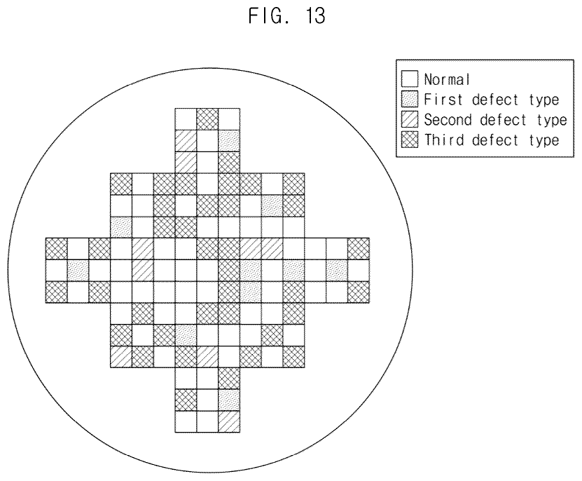

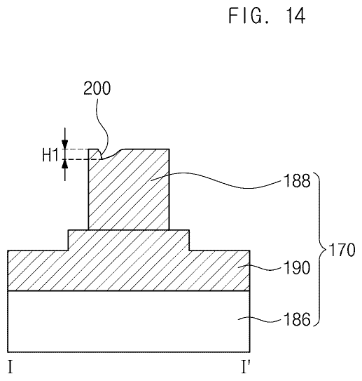

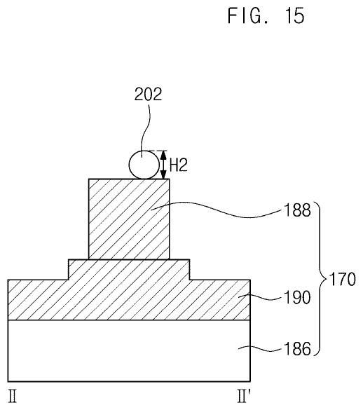

FIG. 12 is an enlarged plan view corresponding to the area S2 of FIG. 7 illustrating the chuck according to one or more embodiments. FIG. 13 is a view illustrating analysis results of the inspection apparatus according to one or more embodiments. FIG. 14 is a cross-sectional view taken along a line I-I′ of FIG. 12. FIG. 15 is a cross-sectional view taken along a line II-II′ of FIG. 12.

Referring to FIGS. 6 and 12 to 15, when the semiconductor manufacturing apparatus, e.g., the exposure apparatus, is inspected, the inspection apparatus 1000 may be moved closer to the exposure apparatus, and the first and second optical systems 100 and 102 may be located inside the exposure apparatus, e.g., the exposure chamber. To move the inspection apparatus 1000, the height adjuster 114 may adjust the height of the fixed support 116 so that the fixed support 116 does not contact the ground. In addition, the moving unit 118 may reduce friction between the inspection apparatus 1000 and the ground to facilitate the movement of the inspection apparatus 1000. After the inspection apparatus 1000 is moved to a desired position, the height adjuster 114 may adjust the height of the fixed support 116 so that the fixed support 116 contacts the ground. Accordingly, the inspection apparatus 1000 may be fixed by the height adjuster 114 and the fixed support 116. The multi-axis rotary stage 120 may move the first and second optical systems 100 and 102 so that the first and second optical systems 100 and 102 are positioned on the upper surface of the chuck 170, which is provided in the exposure apparatus.

A plurality of inspection areas may be defined (formed) in the upper surface of the chuck 170. The first optical system 100 may obtain the two-dimensional images of the inspection areas while being moved by the multi-axis rotary stage 120. The two-dimensional images of the inspection areas are shown in FIG. 13.

Then, the controller 106 may analyze the two-dimensional images to determine the presence or absence of the defective portion 200 or 202. When the defective portion 200 or 202 is present, the controller 106 may analyze the two-dimensional images to identify the position of the defective portion 200 or 202. In addition, the controller 106 may calculate (obtain) the size of the defective portion 200 or 202. Further, the controller 106 may classify the types of the defective portions. The types of the defective portion may be defined previously. The types of the defective portion may be defined in advance based on the sizes and shapes of the defective portions. As shown in FIG. 13, the types of the defective portion may include first, second, and third defect types.

The second optical system 102 may obtain the three-dimensional profile data of the upper surface of the chuck body 186 and the exposed surface of each of the support pillars 188. The second optical system 102 may obtain the three-dimensional profile data of each of the support pillars 188. According to one or more embodiments, the second optical system 102 may obtain the three-dimensional profile data of some of the support pillars 188. Which support pillars 188 are to be inspected by the second optical system 102 may be determined in advance. As an example, the support pillars 188 classified as having the third defect type may be used as the inspection target to obtain the three-dimensional profile data. The controller 106 may analyze the two-dimensional image, and based on that analysis, may calculate (obtain) the position of the support pillars 188 for which the three-dimensional profile data are required. The support pillars 188 for which the three-dimensional profile data are required may be used as the inspection target for the second optical system 102.

Then, the controller 106 may analyze the three-dimensional profile data. When the defective portion 200 or 202 is present, the controller 106 may analyze the three-dimensional profile data to calculate (obtain) at least one of the size of the defective portion, the height of the defective portion, and the depth of the defective portion. Further, the controller 106 may calculate (obtain) the height of each of the support pillars 188 if necessary.

The defective portion 200 or 202 may have one of various forms. As an example, a first defective portion 200 may be a recess formed in the upper surface of the support pillar 188 as shown in FIG. 14. As an example, the first defective portion 200 may occur when a coated portion of the upper surface of the support pillar 188 is removed. The controller 106 may calculate (obtain) a size and a height H1 of the first defective portion 200. According to one or more embodiments, a second defective portion 202 may be a foreign substance located on the upper surface of the support pillar 188 as shown in FIG. 15. The controller 106 may calculate (obtain) a size and a height H2 of the second defective portion 202. As shown in FIG. 12, both the defective portions 200 and 202 may occur. According to one or more embodiments, one of the defective portions 200 and 202 may occur.

After the inspection of the upper surface of the chuck 170 is performed by the first optical system 100, the upper surface of the chuck 170 may be inspected by the second optical system 102. As an example, the first optical system 100 may obtain the two-dimensional images of the inspection areas while being moved by the multi-axis rotary stage 120. When the two-dimensional images with respect to all the inspection areas are obtained, the second optical system 102 may obtain the three-dimensional profile data of the inspection areas while being moved by the multi-axis rotary stage 120. For example, the first and second optical systems 100 and 102 may move over the inspection areas twice by the multi-axis rotary stage 120 to obtain the two-dimensional images and the three-dimensional profile data. According to one or more embodiments, the first and second optical systems 100 and 102 may move over the inspection areas once by the multi-axis rotary stage 120 to obtain the two-dimensional images and the three-dimensional profile data. The first optical system 100 may obtain the two-dimensional image in a first inspection area. Then, the second optical system 102 may obtain the three-dimensional profile data in the first inspection area. Next, the first and second optical systems 100 and 102 may be moved to a second inspection area by the multi-axis rotary stage 120.

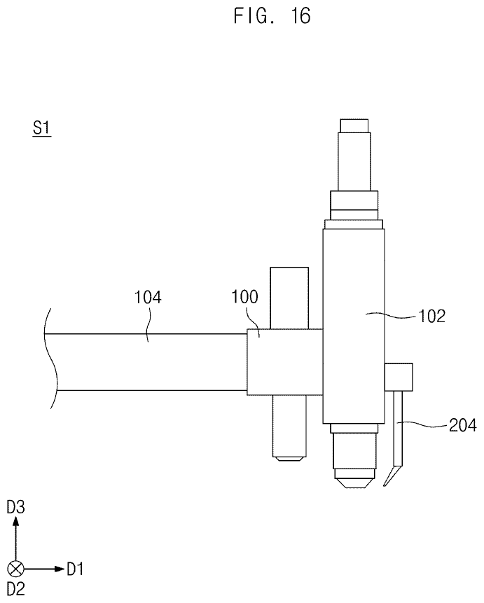

FIG. 16 is an enlarged lateral view corresponding to the area S1 of FIG. 2 and illustrating the inspection apparatus 1000 according to one or more embodiments.

Referring to FIG. 16, the inspection apparatus 1000 may further include a gas spray device 204. The gas spray device 204 may be located adjacent to the first and second optical systems 100 and 102, however, embodiments are not limited thereto. The gas spray device 204 may spray gas toward the chuck 170. For example, the gas spray device 204 may spray the gas toward the upper surfaces of the support pillars 188. Foreign substances on the upper surfaces of the support pillars 188 may be removed by the gas sprayed from the gas spray device 204. The controller 106 may classify, from the three-dimensional profile data of each of the support pillars 188, the support pillars 188 having the foreign substances and may operate the gas spray device 204 to spray the gas toward the upper surfaces of the classified support pillars 188. The inspection apparatus 1000 according to one or more embodiments may further include a gas storage device and a gas transmission line to spray the gas. The gas sprayed from the gas spray device 204 may be helium or nitrogen, however, embodiments are not limited thereto.

In the semiconductor manufacturing apparatuses, the chuck 170 may be a device to hold the substrate 192 and to move the substrate 192. In addition, the chuck 170 may include the support pillars 188 protruded from the upper surface of the chuck body 186 to more efficiently hold the substrate 192. When the substrate 192 is held by the chuck 170, the substrate 192 may be held by the upper surfaces of the support pillars 188 or loaded on the upper surfaces of the support pillars 188. Accordingly, a degree of flatness of the substrate 192 held by the chuck 170 may be determined by the upper surfaces of the support pillars 188. The flatness of the substrate 192 may be a factor that determines the reliability of the semiconductor manufacturing process when the manufacturing process by the semiconductor manufacturing apparatus is performed.

In the above embodiments, the inspection target of the inspection apparatus 1000 may be the chuck 170 that holds the substrate 192, however, embodiment are not limited thereto. In one or more embodiments, the inspection target of the inspection apparatus 1000 may be the reticle stage 180 holding the reticle, the chuck base 172 supporting the chuck 170, or the substrate 192.

According to one or more embodiments, the first and second optical systems 100 and 102 may obtain the two-dimensional image and the three-dimensional profile data of the upper surfaces of the support pillars 188. Accordingly, when the defective portion occurs in at least one of the support pillars 188, the shape of the defective portion may be more precisely inspected. The chuck 170 may be cleaned after the inspection. Therefore, the inspection target, e.g., the chuck, may be cleaned by a cleaning method appropriate for the shape of the defective portion. For example, a suitable cleaning method may be suggested for each type of the defective portions. Accordingly, the efficiency of maintenance work for the semiconductor manufacturing apparatus may be enhanced.

According to one or more embodiments, the second optical system 102 may obtain the three-dimensional profile data of each of the support pillars 188. In addition, the controller 106 may analyze the three-dimensional profile of the defective portion in each of the support pillars 188 based on the three-dimensional profile data. The cause of the defective portion in each of the support pillars 188 may be identified by this analysis. Accordingly, appropriate measures may be taken based on the identified cause. Thus, the efficiency of the maintenance work for the semiconductor manufacturing apparatus may be enhanced.

According to one or more embodiments, the inspection apparatus 1000 may be separated from the units of the semiconductor manufacturing apparatus and may inspect the chuck 170 provided in the semiconductor manufacturing apparatus. In a case where the optical system for inspection is required to be installed inside the semiconductor manufacturing apparatus, defects may occur in the semiconductor manufacturing apparatus due to the attachment or detachment of the optical system. In addition, the foreign substance generated from the optical system may move into the semiconductor manufacturing apparatus. According to one or more embodiments, the inspection apparatus 1000 may include the supporter 104 having the cantilever structure. In addition, the first and second optical systems 100 and 102 may be coupled with and/or connected to the second end portion of the supporter 104. Due to the cantilever structure, the supporter 104 and the first and second optical systems 100 and 102 may have the shape protruded from the inspection body 122 of the inspection apparatus 1000. When the inspection apparatus 1000 inspects the chuck 170, the first and second optical systems 100 and 102 may be located inside the semiconductor manufacturing apparatus, and the inspection body 122 may be located outside the semiconductor manufacturing apparatus. During the inspection, the first and second optical systems 100 and 102 and the inspection body 122 may be spaced apart from the units of the semiconductor manufacturing apparatus. For example, the first and second optical systems 100 and 102 may inspect the chuck 170 in a non-contact manner. Accordingly, the defects caused by the attachment or detachment between the inspection apparatus 1000 with the semiconductor manufacturing apparatus may be prevented. In addition, the foreign substance generated by the inspection apparatus 1000 may be prevented from moving into the semiconductor manufacturing apparatus. Further, the vibration from the inspection apparatus may not be transmitted to the semiconductor manufacturing apparatus.

According to one or more embodiments, the inspection apparatus 1000 may be portable. Therefore, a plurality of semiconductor manufacturing apparatuses may be inspected using the inspection apparatus 1000, and thus, inspection costs may be reduced.

The inspection apparatus 1000 according to one or more embodiments may include the shielding structure 108. The shielding structure 108 may be provided on and/or cover a portion of the multi-axis rotary stage 120. The shielding structure 108 may reduce the foreign substances generated by the multi-axis rotary stage 120 from moving to the semiconductor manufacturing apparatus. Accordingly, the reliability of the semiconductor manufacturing process may be enhanced.

According to one or more embodiments, the inspection apparatus may classify the types of defective portions occurring on the upper surface of the chuck. In addition, the three-dimensional profile data of each of the defective portions may be analyzed. Thus, the timing for cleaning and replacing the chuck may be determined appropriately, and it is possible to minimize unnecessary cleaning operations and replacements.

According to one or more embodiments, the inspection apparatus may inspect the chuck provided inside the semiconductor manufacturing apparatus while being spaced apart from the units of the semiconductor manufacturing apparatus. Accordingly, defects caused by the attachment or detachment between the inspection apparatus and the semiconductor manufacturing apparatus may be prevented. In addition, the vibration from the inspection apparatus may not be transmitted to the semiconductor manufacturing apparatus. Further, it is possible to minimize the movement of foreign substances generated by the inspection apparatus toward the semiconductor manufacturing apparatus.

While embodiments have been described with reference to the figures, it will be understood by those of ordinary skill in the art that various changes in form and details may be made therein without departing from the spirit and scope as defined by the following claims and their equivalents.

What is claimed is:

1. An inspection apparatus comprising:
a supporter extending in a first direction;
an inspection body connected to a first end portion of the supporter to support the supporter; and
a first optical system and a second optical system connected to a second end portion of the supporter opposite to the first end portion of the supporter,
wherein the first optical system is configured to obtain a two-dimensional image of a first surface of a chuck, and the second optical system is configured to obtain three-dimensional profile data of the first surface of the chuck.

2. The inspection apparatus of claim 1, wherein the inspection body comprises at least one processor configured to analyze the two-dimensional image and the three-dimensional profile data.

3. The inspection apparatus of claim 2, wherein, based on a defective portion occurring at a specific position on the first surface of the chuck, the at least one processor is configured to analyze the three-dimensional profile data of the defective portion to obtain at least one of a size of the defective portion, a height of the defective portion, and a depth of the defective portion.

4. The inspection apparatus of claim 2, wherein the inspection body further comprises:
a surface plate; and
a multi-axis rotary stage on the surface plate, the first end portion of the supporter is being connected to the multi-axis rotary stage, and the supporter being configured to move in two dimensions and rotate by the multi-axis rotary stage.

5. The inspection apparatus of claim 1, wherein the chuck comprises a protrusion portion protruding in a second direction perpendicular to the first direction,
wherein the first surface of the chuck comprises an exposed surface of the protrusion portion, and
wherein the three-dimensional profile data comprises three-dimensional profile data of the protrusion portion.

6. The inspection apparatus of claim 1, wherein the first optical system has a resolution from 500 nm to 1 μm.

7. The inspection apparatus of claim 1, wherein the second optical system has a resolution from 1 nm to 900 nm.

8. The inspection apparatus of claim 1, wherein the second optical system comprises a white light interference system.

9. The inspection apparatus of claim 1, wherein the inspection body is portable, and the chuck is installed in semiconductor manufacturing apparatus.

10. The inspection apparatus of claim 9, wherein, based on the two-dimensional image and the three-dimensional profile data of the first surface of the chuck being obtained, the first optical system and the second optical system are inside the semiconductor manufacturing apparatus, the inspection body is outside the semiconductor manufacturing apparatus, and the first optical system and the second optical system, the supporter, and the inspection body are spaced apart from the semiconductor manufacturing apparatus.

11. The inspection apparatus of claim 1, further comprising a gas spray device adjacent to the second optical system,
wherein the gas spray device is configured to spray a gas to the chuck.

12. An inspection apparatus comprising:
a first optical system configured to obtain a two-dimensional image of a first surface of a chuck that comprises a chuck body and support pillars on the chuck body;
a second optical system configured to obtain three-dimensional profile data of the support pillars;
a supporter extending in a first direction; and
an inspection body comprising at least one processor configured to analyze the two-dimensional image and the three-dimensional profile data,
wherein the inspection body is connected to a first end portion of the supporter, and the first optical system and the second optical system are connected to a second end portion of the supporter opposite to the first end portion of the supporter.

13. The inspection apparatus of claim 12, wherein first surfaces of the support pillars are spaced apart from each other in the first direction and configured to hold a substrate, and
wherein the first surface of the chuck comprises a first surface of the chuck body and exposed surfaces of the support pillars.

14. The inspection apparatus of claim 12, wherein the two-dimensional image comprises images of first surfaces of the support pillars, and the at least one processor is configured to determine defects in the support pillars based on data obtained by the analysis by the inspection body.

15. The inspection apparatus of claim 12, wherein, based on a defective portion occurring in at least one of the support pillars, the at least one processor is further configured to analyze three-dimensional profile data of the defective portion to obtain at least one of a size of the defective portion, a height of the defective portion, and a depth of the defective portion.

16. The inspection apparatus of claim 12, wherein the inspection body is portable, and the chuck is installed in an exposure apparatus.

17. The inspection apparatus of claim 12, wherein the inspection body further comprises:
a surface plate; and
a multi-axis rotary stage on the surface plate, the first end portion of the supporter being connected to the multi-axis rotary stage, and a portion of the supporter, comprising the second end portion of the supporter, and the first optical system and the second optical system are protruded outward from the inspection body.

18. The inspection apparatus of claim 12, wherein the at least one processor is further configured to analyze the two-dimensional image to classify types of defective portions occurring in the first surfaces of the support pillars.

19. The inspection apparatus of claim 12, further comprising a gas spray device configured to spray a gas to the support pillars.

20. An inspection apparatus comprising:
a first optical system configured to obtain a two-dimensional image of a first surface of an inspection target;
a second optical system configured to obtain three-dimensional profile data of the first surface of the inspection target;
a supporter extending in a first direction; and
an inspection body comprising at least one processor configured to analyze the two-dimensional image and the three-dimensional profile data to obtain at least one of a size of the three-dimensional profile data of the first surface, a height of the three-dimensional profile data of the first surface, and a depth of the three-dimensional profile data of the first surface,
wherein the inspection body is connected to a first end portion of the supporter, and the first optical system and the second optical system are connected to a second end portion of the supporter opposite to the first end portion of the supporter.
